(19) United States
(12) Patent Application Publication
(10) Pub. No.: US 2020/0106012 A1
(43) Pub. Date: Apr. 2, 2020

(54) METHODS OF FORMING NICKEL-CONTAINING FILMS

(71) Applicant: Applied Materials, Inc., Santa Clara, CA (US)

(72) Inventors: Hung Nguyen, San Jose, CA (US); Liqi Wu, San Jose, CA (US); Feng Q. Liu, San Jose, CA (US); Jeffery W. Anthis, San Jose, CA (US); Ria Someshwar, Mountain View, CA (US); Nicolas Louis Gabriel Breil, Alviso, CA (US)

(73) Assignee: Applied Materials, Inc., Santa Clara, CA (US)

(21) Appl. No.: 16/583,496

(22) Filed: Sep. 26, 2019

Related U.S. Application Data
(60) Provisional application No. 62/738,065, filed on Sep. 28, 2018.

(51) Int. Cl. H01L 45/00; C23C 16/40

(52) U.S. Cl. CPC H01L 45/1616; H01L 45/146; C23C 16/406; H01L 45/1233

(57) ABSTRACT

Exemplary methods of forming a nickel-containing film may include simultaneously flowing a nickel-containing precursor and an oxygen-containing precursor into a semiconductor processing chamber. The methods may include forming a first layer of a nickel-and-oxygen-containing film overlying a substrate housed within the semiconductor processing chamber. The methods may include halting the simultaneous flow. The methods may include flowing a first precursor selected from the nickel-containing precursor and the oxygen-containing precursor into the semiconductor processing chamber. The methods may include flowing a second precursor selected from the nickel-containing precursor and the oxygen-containing precursor into the semiconductor processing chamber. The second precursor may be different from the first precursor. The methods may also include forming a second layer of the nickel-and-oxygen-containing film overlying the first layer of the nickel-and-oxygen-containing film.

### CROSS-REFERENCES TO RELATED APPLICATIONS

This application claims the benefit of U.S. Provisional Patent Application No. 62/738,065, filed on Sep. 28, 2018, and which is hereby incorporated by reference in its entirety for all purposes.

### TECHNICAL FIELD

The present technology relates to semiconductor processes and equipment. More specifically, the present technology relates to producing nickel-containing films on semiconductor substrates.

### BACKGROUND

Integrated circuits are made possible by processes which produce intricately patterned material layers on substrate surfaces. Producing patterned material on a substrate requires controlled methods for deposition and removal of materials. However, with new device designs, producing high quality layers of material may be challenging.

Thus, there is a need for improved systems and methods that can be used to produce high quality devices and structures. These and other needs are addressed by the present technology.

### SUMMARY

Exemplary methods of forming a nickel-containing film may include simultaneously flowing a nickel-containing precursor and an oxygen-containing precursor into a semiconductor processing chamber. The methods may include forming a first layer of a nickel-and-oxygen-containing film overlying a substrate housed within the semiconductor processing chamber. The methods may include halting the simultaneous flow. The methods may include flowing a first precursor selected from the nickel-containing precursor and the oxygen-containing precursor into the semiconductor processing chamber. The methods may include flowing a second precursor selected from the nickel-containing precursor and the oxygen-containing precursor into the semiconductor processing chamber. The second precursor may be different from the first precursor. The methods may also include forming a second layer of the nickel-and-oxygen-containing film overlying the first layer of the nickel-and-oxygen-containing film.

In some embodiments, subsequent flowing the first precursor, the methods may also include halting flow of the first precursor, and purging the semiconductor processing chamber prior to flowing the second precursor. The methods may also include, subsequent flowing the second precursor, halting flow of the second precursor, purging the semiconductor processing chamber, and repeating flowing the first precursor and flowing the second precursor in at least one additional cycle. The methods may be performed while maintaining vacuum conditions throughout each operation of the method. A pressure may be maintained below or about 50 Torr during each operation of the method. Forming the first layer of the nickel-and-oxygen-containing film and forming the second layer of the nickel-and-oxygen-containing film may each be performed at a substrate temperature above or about 200° C. The second layer of the nickel-and-oxygen-containing film may be characterized by a carbon content between about 1 atomic % and about 20 atomic %.

Some embodiments of the present technology may also encompass a semiconductor structure. The structure may include a first layer disposed in contact with a substrate material the first layer may include an oxide. The structure may also include a second layer disposed along the first layer. The second layer may include nickel oxide, and the semiconductor structure may be characterized by a substantially uniform nickel concentration about an exterior edge of the substrate material. The substrate material in contact with the first layer may be or include a transition metal. The substrate material in contact with the first layer may include a layer of iridium metal. The first layer may be or include at least one of aluminum, titanium, or nickel. The structure may also include a third layer disposed along the second layer. The third layer may include an oxide of at least one of aluminum, titanium, or nickel. The second layer may be characterized by a carbon content below or about 20 atomic %.

Some embodiments of the present technology may also encompass a method of forming a nickel-containing film. The method may include forming a first layer of an oxygen-containing film overlying a metal-material housed within a semiconductor processing chamber. The method may include flowing a first precursor selected from a nickel-containing precursor and an oxygen-containing precursor into the semiconductor processing chamber. The method may include flowing a second precursor selected from the nickel-containing precursor and the oxygen-containing precursor into the semiconductor processing chamber. The second precursor may be different from the first precursor. The method may also include forming a second layer comprising a nickel-and-oxygen-containing film overlying the first layer of the nickel-and-oxygen-containing film.

In some embodiments, the first layer may be or include nickel, and the method may include simultaneously flowing a nickel-containing precursor and an oxygen-containing precursor into the semiconductor processing chamber to produce the first layer. The method may further include, subsequent forming the first layer, performing a densification of the first layer subsequent forming the first layer. The densification may include one or more of a thermal anneal or a plasma treatment. The method may also include, subsequent flowing the first precursor, halting a flow of the first precursor, and purging the semiconductor processing chamber prior to flowing the second precursor. The method may also include halting a flow of the second precursor, purging the semiconductor processing chamber, and repeating flowing the first precursor and flowing the second precursor in at least one additional cycle. The first layer and the second layer may be characterized by a thickness less than or about 500 nm. The second layer including the nickel-and-oxygen-containing film may be characterized by a carbon content between about 1 atomic % and about 20 atomic %. Forming the first layer of the oxygen-containing film and forming the second layer comprising the nickel-and-oxygen-containing film may each be performed at a substrate temperature greater than or about 300° C., and at a chamber pressure greater than or about 0.5 Torr.

Such technology may provide numerous benefits over conventional systems and techniques. For example, the processes may provide improved film formation, which may be characterized by limited defects at film interfaces. Additionally, the processes may afford device development that may stably incorporate carbon and other materials into produced films. These and other embodiments, along with many of their advantages and features, are described in more detail in conjunction with the below description and attached figures.

### BRIEF DESCRIPTION OF THE DRAWINGS

A further understanding of the nature and advantages of the disclosed technology may be realized by reference to the remaining portions of the specification and the drawings.

FIG. 1 shows a top plan view of one embodiment of an exemplary processing system according to some embodiments of the present technology.

FIG. 2 shows exemplary operations in a method of film formation according to some embodiments of the present technology.

FIGS. 3A-3C show cross-sectional views of substrates being processed according to some embodiments of the present technology.

FIG. 4 shows exemplary operations in a method of film formation according to some embodiments of the present technology.

Several of the figures are included as schematics. It is to be understood that the figures are for illustrative purposes, and are not to be considered of scale unless specifically stated to be of scale. Additionally, as schematics, the figures are provided to aid comprehension and may not include all aspects or information compared to realistic representations, and may include exaggerated material for illustrative purposes.

In the appended figures, similar components and/or features may have the same reference label. Further, various components of the same type may be distinguished by following the reference label by a letter that distinguishes among the similar components. If only the first reference label is used in the specification, the description is applicable to any one of the similar components having the same first reference label irrespective of the letter.

### DETAILED DESCRIPTION

As devices produced in semiconductor processing continue to shrink, uniformity, material quality, process control, and repeatability are becoming more challenging from process to process. To continue to improve device performance at reduced scale, alternative films and processes are being investigated for additional performance improvements relative to conventional devices.

For example, conventional memory structures include particular limitations. Dynamic random-access memory is a structure that, although characterized by relatively beneficial speed, is volatile. Accordingly, the memory tends to lose data when system power is off. Flash memory does not suffer from the loss, and maintains data throughout power cycling, however, the process of reading and writing is performed in multiple cycles, which may be a slower process. Accordingly, improved memory structures are being developed with a variety of newer material layers. For example, conductive bridging RAM, oxide RAM, magnetic RAM, resistive RAM, and other memory structures are being developed. Many of these structures include new material layers utilizing transition metals or metalloids, which may boost operational characteristics of produced cells.

Nickel oxide is one type of material that may be incorporated in memory structures in one or more ways. For example, the material may be included as a switching medium between two electrodes. However, conventional technologies have struggled with fabricating high-quality nickel oxide materials due to defects that may develop at material interfaces. For example, in some formations where nickel oxide is sought to be formed on metal-containing materials, one or more challenges may occur. When formed by atomic layer deposition, nickel-rich defects may often form at a boundary between the nickel oxide film and the underlying metal-containing film. When other formation or deposition techniques are used, porous and less stable films may be formed, which may cause integration issues downstream. Accordingly, conventional techniques have struggled to produce or incorporate high-quality nickel oxide films.

The present technology overcomes these issues by producing nickel-containing films that may be substantially or essentially devoid of edge defects that may otherwise degrade device performance. By performing a multi-operational deposition, high-quality films may be produced according to embodiments of the present technology. Although the remaining disclosure will routinely identify specific structures, such as memory, for which the present structures and methods may be employed, it will be readily understood that the systems and methods are equally applicable to any number of structures and devices that may benefit from the incorporation of nickel oxide films. Accordingly, the technology should not be considered to be so limited as for use with any particular structures alone. Moreover, although an exemplary tool system will be described to provide foundation for the present technology, it is to be understood that the present technology can be produced in any number of semiconductor processing chambers and tools that may perform some or all of the operations to be described.

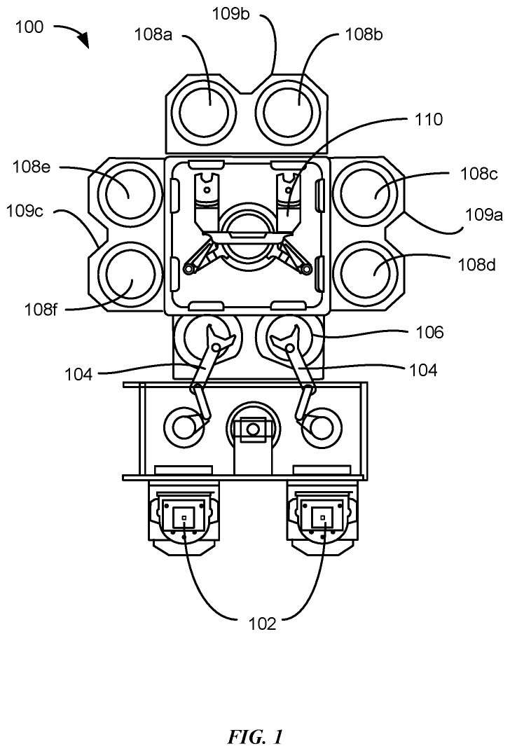

FIG. 1 shows a top plan view of one embodiment of a processing system 100 of deposition, etching, baking, and curing chambers according to some embodiments of the present technology. In the figure, a pair of front opening unified pods (FOUPs) 102 supply substrates of a variety of sizes that are received by robotic arms 104 and placed into a low pressure holding area 106 before being placed into one of the substrate processing chambers 108a-f, positioned in tandem sections 109a-c. A second robotic arm 110 may be used to transport the substrate wafers from the holding area 106 to the substrate processing chambers 108a-f and back. Each substrate processing chamber 108a-f, can be outfitted to perform a number of substrate processing operations including the dry etch processes described herein in addition to cyclical layer deposition (CLD), atomic layer deposition (ALD), chemical vapor deposition (CVD), physical vapor deposition (PVD), etch, pre-clean, anneal, plasma processing, degas, orientation, and other substrate processes.

The substrate processing chambers 108a-f may include one or more system components for depositing, annealing, curing and/or etching a material film on the substrate or wafer. In one configuration, two pairs of the processing chambers, e.g., 108c-d and 108e-f, may be used to deposit material on the substrate, and the third pair of processing chambers, e.g., 108a-b, may be used to cure, anneal, or treat the deposited films. In another configuration, all three pairs of chambers, e.g., 108a-f, may be configured to both deposit and cure a film on the substrate. Any one or more of the processes described may be carried out in additional chambers separated from the fabrication system shown in different embodiments. It will be appreciated that additional configurations of deposition, etching, annealing, and curing chambers for material films are contemplated by system 100. Additionally, any number of other processing systems may be utilized with the present technology, which may incorporate chambers for performing any of the specific operations. In some embodiments, chamber systems which may provide access to multiple processing chambers while maintaining a vacuum environment in various sections, such as the noted holding and transfer areas, may allow operations to be performed in multiple chambers while maintaining a particular vacuum environment between discrete processes.

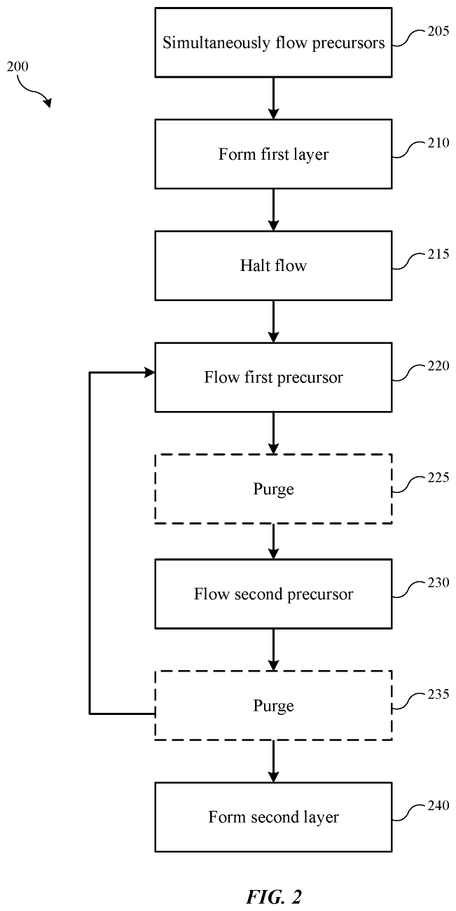

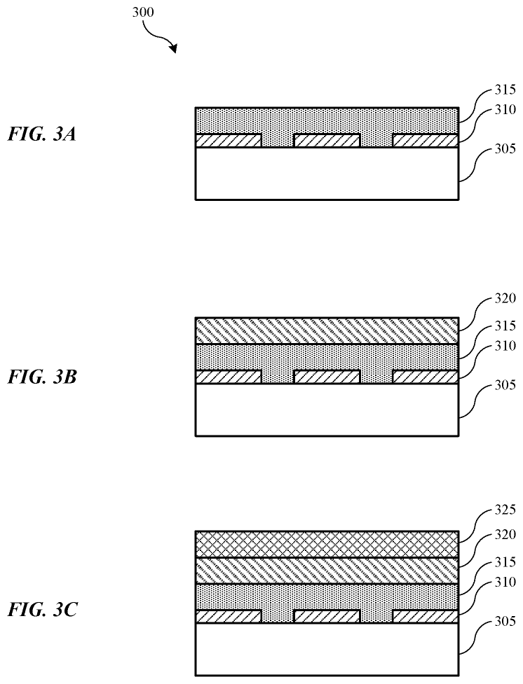

System 100, or more specifically chambers incorporated into system 100 or other processing systems, may be used to produce nickel oxide films according to some embodiments of the present technology. FIG. 2 shows exemplary operations in a method 200 of film formation according to some embodiments of the present technology. Method 200 may be performed in one or more processing chambers, such as chambers incorporated in system 100, for example. Method 200 may or may not include one or more operations prior to the initiation of the method, including front-end processing, deposition, etching, polishing, cleaning, or any other operations that may be performed prior to the described operations. The method may include a number of optional operations as denoted in the figure, which may or may not be specifically associated with some embodiments of methods according to the present technology. Method 200 describes operations shown schematically in FIGS. 3A-3C, the illustrations of which will be described in conjunction with the operations of method 200. It is to be understood that FIG. 3 illustrates only partial schematic views with limited details, and in some embodiments a substrate may contain any number of transistor or semiconductor sections having aspects as illustrated in the figures, as well as alternative structural aspects that may still benefit from any of the aspects of the present technology.

Method 200 may involve optional operations to develop the semiconductor structure to a particular fabrication operation. Although in some embodiments method 200 may be performed on a base structure, in some embodiments the method may be performed subsequent transistor or other material formation. As illustrated in FIG. 3A, the semiconductor structure may represent a device 300 after front-end or other processing has been completed. For example, substrate 305 may be a planar material, or may be a structured device, which may include multiple materials configured as posts, trenches, or other structures as would be understood are similarly encompassed by the present technology. Substrate 305 may include any number of conductive and dielectric materials including metals, including transition metals, post-transition metals, metalloids, oxides, nitrides, and carbides of any of these materials, as well as any other materials that may be incorporated within a structure.

One or more material layers may be formed over some or all of substrate 305. For example, in some embodiments a metal layer 310 may be formed overlying substrate 305. The metal layer 310 may be a continuous layer across the substrate, or may be intermittently formed across the surface of the substrate as illustrated. In one non-limiting example, a metal may be formed intermittently across the substrate 305. The metal may include tantalum, praseodymium, hafnium, titanium, iridium, rhodium, platinum, or any other material that may operate as an electrode in a memory structure or may be present in alternative structures, for example. The metal layer 310 may be etched to produce the intermittent pattern in some embodiments, which either through etching or other formation may expose a portion of substrate 305 between segments of metal layer 310. Although schematically illustrated as including straight sidewalls, the formation or removal process of metal layer 310 may produce angled sidewalls. Thus, in some embodiments, the segments of metal layer 310 may be characterized by a frustum shape, or by an angled surface along one or more faces of the segments. Substrate 305, which may include metal layer 310, may be housed or positioned in a processing region of a semiconductor processing chamber, and method 200 may be performed to form a nickel-containing material on the substrate.

Method 200 may include simultaneously flowing or co-flowing a nickel-containing precursor and an oxygen-containing precursor into the semiconductor processing chamber at operation 205. Chamber conditions may be set to cause interaction between the precursors, which may allow formation or deposition of a first layer of a nickel-and-oxygen-containing film overlying the substrate at operation 210. Once the first layer of the nickel-and-oxygen-containing film has been formed to a target thickness, flow of the precursors may be halted at operation 215. The chamber may or may not be purged after operation 215, and chamber conditions may or may not be altered. In some embodiments the substrate may be transferred to a different processing chamber, although in some embodiments all operations of method 200 may be performed in a single chamber. FIG. 3A illustrates the first layer 315 formed overlying the metal layer 310. Additionally, first layer 315 may extend and contact substrate 305 in regions between the segments of metal layer 310, and thus may extend along a height of each segment of metal layer 310.

A cyclic process may then be performed to produce a second layer of material overlying the first layer of material. The process may be a half-reaction process, such as atomic layer deposition in some embodiments. For example, the same or different nickel-containing precursors and oxygen-containing precursors may be used in forming the second layer of material, and the precursors may be flowed individually into the processing chamber to develop the second layer of material. Either precursor may be flowed into the processing chamber first, and in some embodiments the nickel-containing precursor may be flowed into the processing chamber and allowed to interact with the first layer of material at operation 220. After an amount of time, the flow of the first precursor may be halted, and the chamber may be purged of the first precursor at optional operation 225.

Subsequently, a second precursor, which may be the other of the two precursors, and may be the oxygen-containing precursor, may be flowed into the processing chamber at operation 230. The second precursor may interact with the first precursor to produce a second layer of film. After a second amount of time, the second precursor flow may also be halted, and another purge may be performed to remove residual second precursor at optional operation 235. One or more of operations 220-235 may be repeated for one or more additional cycles, which may increase the film thickness up to or towards a target film thickness. These cycles may produce a second layer of the nickel-and-oxygen containing film at operation 240, which may overly the first layer produced previously. As illustrated in FIG. 3B, second layer 320 may be formed across a surface of first layer 315, which may be a surface opposite a surface of first layer 315 in contact with one or more of substrate 305 and/or metal layer 310. Although second layer 320 may be different from first layer 310 as described further below, in some embodiments the layers may both be or include a nickel oxide material.

As explained previously, forming nickel oxide layers with conventional chemical-vapor deposition may produce lower quality films. For example, the film produced may be less stable, which may cause uniformity issues during subsequent operations. For example, outgassing during subsequent processes may increase porosity in the film, which may reduce planarity or material properties of the film produced. Consequently, when an additional electrode is formed overlying the material to produce a memory structure, for example, device performance may be compromised. Cyclically formed films may be characterized by increased density, and may produce more stable films. However, as noted above, the formation may produce nickel-rich protrusions or defects on underlying metallic materials.

For example, as previously noted, formation of metal layer 310 may produce beveled or chamfered edges extending towards substrate 305. This may effectively expose an additional facet of the metal along the angle, which may react differently with the nickel-containing precursor and/or the oxygen-containing precursor. This may produce nickel-rich protrusions, the inconsistency of which relative to the bulk film may degrade the electrical behavior or performance of the produced structure. Among other factors that may affect the formation of these protrusions, an atomic layer deposition process may be characterized by a longer nucleation time, which may expose the underlying metal layer to one or both of the nickel-containing precursor and the oxygen-containing precursor, which may contribute to the formation of the protrusions.

By performing a multi-operational process, such as described with method 200, some embodiments of the present technology may overcome the issues related to both individual film formation techniques described. For example, by producing an initial layer of nickel oxide with a co-flow operation, film nucleation time may be reduced, which may limit the exposure of the underlying metal layer. By switching to a cyclic process subsequent metal layer coverage, a higher quality film may be produced, while limiting or preventing the formation of the nickel-rich protrusions. Accordingly, the present technology may produce more stable, higher quality films, which may be used in a host of devices and structures. Consequently, produced films may be characterized by a substantially uniform nickel concentration about an exterior edge of the substrate material, and may not include nickel-rich protrusions about the interface with the underlying metal material. For example, the produced films may be characterized by a nickel concentration proximate the angled or vertical sidewalls of metal layer 310 segments within about 20% of the nickel concentration within the bulk of second layer 320. In some embodiments the nickel concentration may be within about 15% of the bulk layer concentration, and may be within about 10% of the bulk layer concentration, 5% of the bulk layer concentration, 1% of the bulk layer concentration, or the nickel concentration proximate the sidewalls of metal layer 310 may be substantially or essentially equal to the concentration within the bulk of second layer 320. For example, when protrusions are formed, the nickel concentration may extend up to or about 80%, up to or about 85%, up to or about 90%, up to or about 95%, or the protrusions may be exclusively, i.e. 100%, nickel, whereas the bulk of the film formed may be less than or about 80% nickel, such as between about 40% to about 60% in one non-limiting embodiment.

However, by utilizing aspects of the present technology, regions about the interface may be within any of the percentages listed for the bulk material, either as a percentage of the stated percentage or as an added percentage on the stated percentage within the listed ranges. Hence, as one non-limiting example, when the bulk material may have any nickel concentration percentage, such as a percentage within a range of between about 40% to about 60%, the regions about the interface as described may be characterized by a nickel concentration of between about 20% to about 80%, down to a range within about 8% of the specific bulk material concentration percentage, or within about 6%, within about 4%, within about 2%, within about 1%, or substantially or essentially equivalent to the bulk material.

A variety of materials may be used for the nickel-containing precursor and the oxygen-containing precursor. Exemplary oxygen-containing precursors may be or include any oxygen-containing precursor. For example the oxygen-containing precursor may be or include water, diatomic oxygen, ozone, a hydroxyl-containing precursor or alcohol, nitrogen-and-oxygen-containing precursors, or any other material including oxygen that may be incorporated with nickel to produce a nickel oxide material.

Exemplary nickel-containing precursors may include any nickel-containing precursor, and in some embodiments may include one or more nickel-containing hydrocarbons or organonickel compounds, such as precursors characterized by one or more nickel-carbon bonds. For example, nickel-containing precursors may be or include nickel alkene complexes, nickel allyl complexes including halide-containing precursors, nickelocene, nickel carbene complexes, or other materials that may include nickel and one or more of hydrogen, carbon, nitrogen, and/or oxygen. Exemplary formulae for nickel-containing precursors may include (R₅C₅)₂Ni, where R may be H or any alkyl group, and nickel-containing alkoxides, which may include as examples only, bis(ethylcyclopentadienyl)nickel, bis(cyclopentadienyl)nickel, bis(methylcyclopentadienyl)nickel, bis(pentamethylcyclopentadienyl)nickel, allyl(cyclopentadienyl)nickel, bis(triphenylphosphone)nickel dichloride, or nickel bis(2,2,6,6-tetramethyl-3,5-heptanedioate). Exemplary nickel-containing precursors may be provided in gaseous form, although liquid and solid precursors may also be used in some embodiments.

Depending on the nickel-containing precursor used, an amount of carbon may be incorporated within the film to produce a nickel oxycarbide film in some embodiments, which may adjust or tune electrical properties within the nickel oxide film. The present technology may include an atomic percentage of carbon within one or both of the first layer and/or the second layer in embodiments. The carbon percentage may be the same or different between the layers, and may include a carbon content between about 0 atomic % and about 50 atomic %. In some embodiments, one or both layers may include a carbon content between or about 1 atomic % and about 40 atomic %, between or about 1 atomic % and about 30 atomic %, between or about 1 atomic % and about 20 atomic %, between or about 1 atomic % and about 10 atomic %, or any other range encompassed by any of these ranges.

Process conditions may also be configured to affect the formation of one or both layers. In some embodiments, the methods may be performed under vacuum, and in some embodiments vacuum conditions may not be broken between operations of the method. Pressure within the system may be maintained at less than or about 100 Torr for any of the operations being performed, and in some embodiments may be maintained at less than or about 80 Torr, less than or about 60 Torr, less than or about 50 Torr, less than or about 40 Torr, less than or about 30 Torr, less than or about 20 Torr, less than or about 10 Torr, less than or about 5 Torr, less than or about 1 Torr, less than or about 0.1 Torr, or less, although formation rates may increase as pressure is maintained or increased between about 0.5 Torr and about 50 Torr in some embodiments.

Temperature may also impact formation of the nickel-containing layers, and in some embodiments a temperature of any of the operations, either individually or collectively, may be performed at temperatures above or about 100° C. One or more operations may also be performed at temperatures above or about 150° C., and may be performed at temperatures above or about 200° C., above or about 250° C., above or about 300° C., above or about 350° C., above or about 400° C., above or about 450° C., above or about 500° C., above or about 550° C., above or about 600° C., or higher. The operational temperatures may be adjusted based on precursors used, for example, as well as on device thermal budgets. For example, in some embodiments a nickel-containing film may be produced as a back-end-of-line operation for which temperature may be maintained below or about 500° C., or lower. Additionally, some precursors may begin to thermally decompose above certain temperatures, and thus operational temperatures may be adjusted to reduce precursor decomposition in some embodiments.

In some embodiments, temperature may also affect carbon content of the first or second layer of the film. For example, in some embodiments the first layer of film may be produced by a simultaneous flow of precursors, which may produce a less stable film in some embodiments. Some embodiments may include a treatment operation, for example, which may densify or otherwise increase the quality of the film produced. For example, a thermal anneal or plasma process may be performed to densify the film, among any other operation to densify the film. When a thermal anneal is performed, or when a plasma treatment is performed, the temperature within the chamber in which the process is performed, may be raised at least 20° C. higher than the deposition or formation temperature. Additionally, the treatment operation may be performed at a temperature that is at least about 30° C. higher than the formation temperature, and may be at least about 40° C. higher, at least about 50° C. higher, at least about 60° C. higher, at least about 70° C. higher, at least about 80° C. higher, at least about 90° C. higher, at least about 100° C. higher, at least about 150° C. higher, at least about 200° C. higher, or higher than the film formation temperature.

The environment may or may not be adjusted during the treatment. For example, the environment may be purged to include an inert precursor only, such as previously noted precursors, or the environment may be or include one or more of oxygen, air, ozone, or a combination, such as ozone and argon, any of which may further modulate carbon percentage and other density or film properties of the formed films. In some embodiments a treatment may not be performed as the cyclic process may be performed at a temperature that may similarly densify the first layer of material. Regardless, the treatment may cause an amount of carbon loss, which may reduce the carbon content within the first layer of material. The loss may be accommodated by increasing as-formed carbon content within the first layer, or the first layer may be characterized by a lower carbon content than the second film in some embodiments, although either layer may be characterized by any of the previously discussed carbon contents.

The first layer and second layer of material may each be formed to any thickness to produce a target overall film thickness. For example, the combined thickness for all incorporated layers may be greater than or about 1 nm, greater than or about 10 nm, greater than or about 50 nm, greater than or about 100 nm, greater than or about 500 nm, or more, as well as any smaller range encompassed by any of these stated ranges. Any constituent layer may occupy any amount of the overall thickness of the layer. In some embodiments the first layer may be thinner than the second layer, which may reduce the limitations of the co-flow process as previously described. Accordingly, in some embodiments the first layer may be less than or about 100 nm, and may be less than or about 50 nm, less than or about 40 nm, less than or about 30 nm, less than or about 20 nm, less than or about 10 nm, less than or about 9 nm, less than or about 8 nm, less than or about 7 nm, less than or about 6 nm, less than or about 5 nm, less than or about 4 nm, less than or about 3 nm, less than or about 2 nm, less than or about 1 nm, or less.

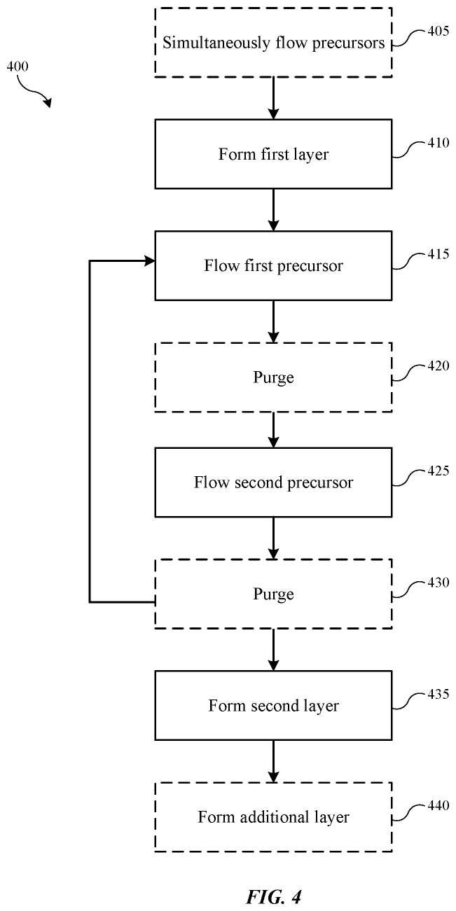

The present technology may also produce combination structures that may include additional materials, as well as additional layers. FIGS. 3A-3C may also illustrate cross- sectional views of substrates being processed according to additional embodiments of the present technology in which first layer 315 may be or include an additional material. For example, as will be discussed with regard to FIG. 4 below, first layer 315 may be or include an additional oxide material that may be compatible with underlying metal layer 310. For example, the first formed layer may be or include aluminum oxide, titanium oxide, or any other oxide that may be characterized by a compatibility with the underlying metal layer. First layer 315 may at least partially operate as a passivation layer to protect the underlying metal layer from the subsequent cyclic formation of nickel oxide, and thus first layer 315, including any of the materials discussed elsewhere, may be of any thickness noted above although the thickness may be less than or about 10 nm to protect the underlying structure, while allowing the bulk of the overall thickness of the multiple layers to be a higher quality nickel oxide material.

FIG. 3C illustrates additional embodiments in which a subsequent layer 325 may be formed overlying the second layer 320. The material of subsequent layer 325 may be a second electrode material in some embodiments, although in some embodiments subsequent layer 325 may represent one or more additional structural layers. For example, an additional oxide layer may be formed overlying the second layer. For example, an aluminum oxide layer, or any other material layer, may be formed over the second layer of material, which may be nickel oxide, for example. The subsequent layer may be characterized by any of the previously noted carbon percentages, which may be similar to, greater than, or less than the incorporation in second layer 320.

FIG. 4 shows exemplary operations in a method 400 of film formation according to some embodiments of the present technology. In some embodiments method 400 may be similar to method 200 described above, and may include any of the operations, processing conditions, or produced film characteristics described above. Method 400 may encompass method 200 as well as additional formations in which an alternative material may be included within the first layer 315, for example. The operations of method 400 may similarly produce one or more structures illustrated in FIG. 3 above, although the method may cover multiple first layer materials. For example, method 400 may optionally include simultaneously flowing precursors at operation 405, and may produce a first layer of material at operation 410. The first layer of material may be similar to the first layer formed in method 200, and may include a nickel-containing precursor and an oxygen-containing precursor. Additionally, the method may form an oxygen-containing material that may include a different material, such as aluminum, titanium, magnesium, or any other oxygen-containing material that may be compatible with the metal of underlying metal layer 310. The layer may or may not include simultaneously flowing precursors in some embodiments.

After formation of the first layer of material, the method may be similar to method 200 described above, and may include the cyclic formation of a nickel oxide material as a second layer of material overlying the first layer. As discussed above, the method may include flowing a first precursor at operation 415, which may be either of the nickel-containing precursor and the oxygen-containing precursor. A purge may be performed at optional operation 420, followed by flowing the second precursor between the nickel-containing precursor and the oxygen-containing precursor at operation 425. A subsequent purge may be performed at optional operation 430, and these operations may be cycled any number of times to produce a second layer of material at operation 435, which may be a nickel oxide material, and which may be characterized by any of the material properties described previously. Method 400 may optionally include forming an additional layer overlying the second layer at optional operation 440. As noted, the additional layer may be another oxide layer, or may be a second metal layer, which may be any of the previously noted metals, and which may operate as an additional electrode in some embodiments.

By performing a multilayer formation encompassed by the various embodiments of the present technology, improved nickel oxide films may be produced. The films may not form protrusions about underlying metal layers, while improving on quality of other conventional films. The processes may allow a number of films to be produced including multilayer films incorporating different oxide materials.

In the preceding description, for the purposes of explanation, numerous details have been set forth in order to provide an understanding of various embodiments of the present technology. It will be apparent to one skilled in the art, however, that certain embodiments may be practiced without some of these details, or with additional details.

Having disclosed several embodiments, it will be recognized by those of skill in the art that various modifications, alternative constructions, and equivalents may be used without departing from the spirit of the embodiments. Additionally, a number of well-known processes and elements have not been described in order to avoid unnecessarily obscuring the present technology. Accordingly, the above description should not be taken as limiting the scope of the technology. Additionally, methods or processes may be described as sequential or in steps, but it is to be understood that the operations may be performed concurrently, or in different orders than listed.

Where a range of values is provided, it is understood that each intervening value, to the smallest fraction of the unit of the lower limit, unless the context clearly dictates otherwise, between the upper and lower limits of that range is also specifically disclosed. Any narrower range between any stated values or unstated intervening values in a stated range and any other stated or intervening value in that stated range is encompassed. The upper and lower limits of those smaller ranges may independently be included or excluded in the range, and each range where either, neither, or both limits are included in the smaller ranges is also encompassed within the technology, subject to any specifically excluded limit in the stated range. Where the stated range includes one or both of the limits, ranges excluding either or both of those included limits are also included.

As used herein and in the appended claims, the singular forms “a”, “an”, and “the” include plural references unless the context clearly dictates otherwise. Thus, for example, reference to “a precursor” includes a plurality of such precursors, and reference to “the layer” includes reference to one or more layers and equivalents thereof known to those skilled in the art, and so forth.

Also, the words “comprise(s)”, “comprising”, “contain(s)”, “containing”, “include(s)”, and “including”, when used in this specification and in the following claims, are intended to specify the presence of stated features, integers, components, or operations, but they do not preclude the presence or addition of one or more other features, integers, components, operations, acts, or groups.

1. A method of forming a nickel-containing film, the method comprising:
simultaneously flowing a nickel-containing precursor and an oxygen-containing precursor into a semiconductor processing chamber;
forming a first layer of a nickel-and-oxygen-containing film overlying a substrate housed within the semiconductor processing chamber;
halting the simultaneous flow;
flowing a first precursor selected from the nickel-containing precursor and the oxygen-containing precursor into the semiconductor processing chamber;
flowing a second precursor selected from the nickel-containing precursor and the oxygen-containing precursor into the semiconductor processing chamber, wherein the second precursor is different from the first precursor; and
forming a second layer of the nickel-and-oxygen-containing film overlying the first layer of the nickel-and-oxygen-containing film.

2. The method of forming a nickel-containing film of claim 1, further comprising, subsequent flowing the first precursor:
halting flow of the first precursor, and
purging the semiconductor processing chamber prior to flowing the second precursor.

3. The method of forming a nickel-containing film of claim 2, further comprising, subsequent flowing the second precursor:
halting flow of the second precursor,
purging the semiconductor processing chamber, and
repeating flowing the first precursor and flowing the second precursor in at least one additional cycle.

4. The method of forming a nickel-containing film of claim 1, wherein the method is performed while maintaining vacuum conditions throughout each operation of the method.

5. The method of forming a nickel-containing film of claim 4, wherein a pressure is maintained below or about 50 Torr during each operation of the method.

6. The method of forming a nickel-containing film of claim 1, wherein forming the first layer of the nickel-and-oxygen-containing film and forming the second layer of the nickel-and-oxygen-containing film are each performed at a substrate temperature above or about 200° C.

7. The method of forming a nickel-containing film of claim 1, wherein the second layer of the nickel-and-oxygen-containing film is characterized by a carbon content between about 1 atomic % and about 20 atomic %.

8. A semiconductor structure comprising:
a first layer disposed in contact with a substrate material, wherein the first layer comprises an oxide; and
a second layer disposed along the first layer, wherein the second layer comprises nickel oxide, and wherein the semiconductor structure is characterized by a substantially uniform nickel concentration about an exterior edge of the substrate material.

9. The semiconductor structure of claim 8, wherein the substrate material in contact with the first layer comprises a transition metal.

10. The semiconductor structure claim 9, wherein the substrate material in contact with the first layer comprises a layer of iridium metal.

11. The semiconductor structure of claim 8, wherein the first layer comprises at least one of aluminum, titanium, or nickel.

12. The semiconductor structure of claim 8, further comprising a third layer disposed along the second layer, wherein the third layer further comprises an oxide of at least one of aluminum, titanium, or nickel.

13. The semiconductor structure of claim 8, wherein the second layer is characterized by a carbon content below or about 20 atomic %.

14. A method of forming a nickel-containing film, the method comprising:
forming a first layer of an oxygen-containing film overlying a metal-material housed within a semiconductor processing chamber;
flowing a first precursor selected from a nickel-containing precursor and an oxygen-containing precursor into the semiconductor processing chamber;
flowing a second precursor selected from the nickel-containing precursor and the oxygen-containing precursor into the semiconductor processing chamber, wherein the second precursor is different from the first precursor; and
forming a second layer comprising a nickel-and-oxygen-containing film overlying the first layer of the nickel-and-oxygen-containing film.

15. The method of forming a nickel-containing film claim 14, wherein the first layer comprises nickel, and wherein the method further comprises simultaneously flowing a nickel-containing precursor and an oxygen-containing precursor into the semiconductor processing chamber to produce the first layer.

16. The method of forming a nickel-containing film claim 14, further comprising, subsequent forming the first layer:
performing a densification of the first layer subsequent forming the first layer, wherein the densification comprises one or more of a thermal anneal or a plasma treatment.

17. The method of forming a nickel-containing film claim 14, further comprising, subsequent flowing the first precursor:
halting a flow of the first precursor,
purging the semiconductor processing chamber prior to flowing the second precursor,
halting a flow of the second precursor,
purging the semiconductor processing chamber, and
repeating flowing the first precursor and flowing the second precursor in at least one additional cycle.

18. The method of forming a nickel-containing film claim 14, wherein the first layer and the second layer are characterized by a thickness less than or about 500 nm.

19. The method of forming a nickel-containing film claim 14, wherein the second layer comprising the nickel-and-oxygen-containing film is characterized by a carbon content between about 1 atomic % and about 20 atomic %.

20. The method of forming a nickel-containing film claim 14, wherein forming the first layer of the oxygen-containing film and forming the second layer comprising the nickel-and-oxygen-containing film are each performed at a substrate temperature greater than or about 300° C., and at a chamber pressure greater than or about 0.5 Torr.
